(19) United States
(12) Patent Application Publication
(10) Pub. No.: US 2022/0383083 A1
(43) Pub. Date: Dec. 1, 2022

(54) METHOD FOR TRAINING A BINARIZED NEURAL NETWORK AND RELATED ELECTRONIC CIRCUIT

(71) Applicants: Commissariat à l'énergie atomique et aux énergies alternatives, Paris (FR); Centre national de la recherche scientifique, Paris (FR); UNIVERSITE PARIS-SACLAY, Gif Sur Yvette (FR)

(72) Inventors: Tifenn HIRTZLIN, Grenoble Cedex 9 (FR); Damien QUERLIOZ, Palaiseau (FR); Elisa VIANELLO, Grenoble Cedex 9 (FR)

(73) Assignees: Commissariat à l'énergie atomique et aux énergies alternatives, Paris (FR); Centre national de la recherche scientifique, Paris (FR); UNIVERSITE PARIS-SACLAY, Gif Sur Yvette (FR)

(21) Appl. No.: 17/664,502

(22) Filed: May 23, 2022

(30) Foreign Application Priority Data
May 25, 2021 (EP) 21305677.3

(51) Int. Cl. G06N 3/063; G06N 3/04; G06N 3/08

(52) U.S. Cl. CPC G06N 3/063; G06N 3/049; G06N 3/0481; G06N 3/084

(57) ABSTRACT

This method for training a binarized neural network, also called BNN, including neurons, with a binary weight for each connection between two neurons, is implemented by an electronic circuit and comprises:
a forward pass including calculating an output vector by applying the BNN on an input vector;
a backward pass including computing an error vector from the calculated output vector, and calculating a new value of the input vector by applying the BNN on the error vector;
a weight update including computing a product by multiplying an element of the error vector with one of the new value of the input vector, modifying a latent variable depending on the product; and updating the weight with the latent variable;

each weight being encoded using a primary memory component;

each latent variable being encoded using a secondary memory component having a characteristic subject to a time drift.

### CROSS-REFERENCE TO RELATED APPLICATIONS

This application is a U.S. non-provisional application claiming the benefit of European Application No. 21 305 677.3, filed on May 25, 2021, which is incorporated herein by reference in its entirety.

### FIELD OF THE INVENTION

The present invention relates to a method for training a binarized neural network, the binarized neural network including input neurons for receiving input values, output neurons for delivering output values and intermediate neurons between the input and output neurons, a respective binary weight being associated to each connection between two respective neurons (synaptic weight), the method being implemented by an electronic circuit using memory devices.

The invention also relates to an electronic circuit for operating such a binarized neural network, in particular for training said binarized neural network.

### BACKGROUND OF THE INVENTION

The invention concerns the field of artificial neural networks, also called ANN, used in many areas of artificial intelligence: image recognition, speech recognition, optimization, etc.

The invention concerns in particular the field of binarized neural networks where both synapses and neurons can take binary values.

Currently, artificial neural networks are used in many areas of artificial intelligence. However, their training, also called learning, place significant demands on storage and computation involving an important energy consumption. This energy is due to the transfer of large quantities of information between the memory and processing units. Actually, there is no system capable of edge learning. Cloud computing platforms are used for the training phase and only the inference is performed at the edge.

Binarized neural networks, also called BNN, can be implemented using digital circuits. Therefore, they are very advanced in terms of hardware implementation. For example, low power implementations of BNN based on resistive memories have been recently proposed in the article “Digital Biologically Plausible Implementation of Binarized Neural Networks with Differential Hafnium Oxide Resistive Memory Arrays” from T. Hirtzlin et al, published in 2020 in Fontiers in Neuroscience.

Further, the article “Latent Weights Do Not Exist: Rethinking Binarized Neural Network Optimization” from K. Helwegen et al, published in 2019 for the 33^{rd} Conference on Neural Information Processing Systems (NeurIPS 2019), describes a Binary Optimizer, referred to as BOP, algorithm designed for training BNN. This article teaches that in contrast to traditional real-valued supervised learning of ANN, with BNN there is the additional constraint to be a binary vector for a solution to a loss function used during the training of the BNN.

Usually, a global optimum to said loss function cannot be found. In real-valued networks an approximate solution via Stochastic Gradient-Descent (SGD) based methods are used instead. This challenge for evaluating the gradient when training a BNN is resolved by introducing during training an additional real value scalar for each synaptic weight, also called latent weight.

However, the BOP algorithm for training BNN and the SGD based methods require a computer and/or an external digital memory to store the latent weights to be implemented.

For training neural networks, the article “Equivalent-accuracy accelerated neural-network training using analogue memory” from S. Ambrogio et al, published in 2018 in Nature, describes an electronic circuit with analogue-memory unit cells, wherein each unit cell contains a pair of phase-change memory devices, also called PCM devices (labelled G+ and G−), and a volatile analogue conductance, in particular a volatile capacitor.

However, the need to add a capacitor per synaptic weight, i.e. per neuron, results in an important area overhead.

In addition, for training BNN, the article “Hybrid Analog-Digital Learning with Differential RRAM Synapses” from T. Hirtzlin et al, published in 2019 for IEEE International Electron Devices Meeting, teaches about the exploitation of the analog properties of a weak RESET in hafnium-oxide RRAM cells, also called OxRAM cells, while using compact and low power digital CMOS.

In contrast to the teaching of the article “A new hardware implementation approach of BNNs based on nonlinear 2T2R synaptic cell” from Z. Zhou et al, published in 2018 for IEEE International Electron Devices Meeting, a simple refresh mechanism allows to avoid saturation according to the article “Hybrid Analog-Digital Learning with Differential RRAM Synapses” from T. Hirtzlin et al.

Nonetheless, this solution suffers from some shortcomings. Firstly, the pulsed RESETs of the OxRAM cells are noisy; secondly, the learning algorithm requires to keep three variables in memory, one has to be stored on a computer or an external digital memory; and thirdly, these devices have limited endurance.

“Training Dynamical Binary Neural Networks with Equilibrium Propagation” from Laydevant et al relates to training dynamical Binary Neural Networks with Equilibrium Propagation.

“Hardware implementation of RRAM based binarized neural networks” from Peng et al concerns the hardware implementation of BNN and describes some examples of nonvolatile memories used for neural networks.

### SUMMARY OF THE INVENTION

An object of the invention is therefore to provide a method and an associated electronic circuit for enabling on-chip training of a binarized neural network, without computer support.

For this purpose, the subject-matter of the invention is a method for training a binarized neural network, the binarized neural network including input neurons for receiving input values, output neurons for delivering output values and intermediate neurons between the input and output neurons, a respective binary weight being associated to each connection between two respective neurons, the method being implemented by an electronic circuit and comprising:
a forward pass step including calculating an output vector by applying the binarized neural network on an input vector in a forward direction from the input neurons to the output neurons;
a backward pass step including computing an error vector between the calculated output vector and a learning output vector and calculating a new value of the input vector by applying the binarized neural network on the error vector in a backward direction from the output neurons to the input neurons; and
a weight update step including, for each binary weight:
   computing a product by multiplying a respective element of the error vector with a respective element of the new value of the input vector;
   modifying a latent variable depending on the product; and
   updating the respective binary weight as a function of the latent variable with respect to a threshold;

each binary weight being encoded using at least one primary memory component;

each latent variable being encoded using at least one secondary memory component, each secondary memory component having a characteristic subject to a time drift,

each one of the primary and secondary memory components being a phase-change memory device.

With the training method according to the invention, each latent variable is encoded using at least one secondary memory component, each secondary memory component having a characteristic subject to a time drift. Therefore, the value of each latent variable drifts over time, in a similar manner to each latent weight verifying an exponential moving average of gradients according to the BOP algorithm for training BNN.

Thus, the training method uses this characteristic of the secondary memory components subject to the time drift to adapt the BOP algorithm for training BNN, so as to enable on-chip learning, i.e. on-chip training, for BNN.

According to other advantageous aspects of the invention, the training method comprises one or several of the following features, taken individually or according to any technically possible combination:
each primary memory component has a characteristic subject to a time drift;
the characteristic subject to the time drift is a conductance;
each binary weight is encoded using two complementary primary memory components connected to a common sense line;
each binary weight depends on respective conductance of the two complementary primary memory components;
each binary weight verifies the following equation:

$$Wbin , ij = sign ( \frac{G ( {W}_{BLb , ij} )}{G ( {W}_{BL , ij} )} )$$

where W_{bin,ij} represents a respective binary weight,

sign is a sign function applied to an operand and issuing the value 1 if the operand is positive and −1 if the operand is negative, and

G(W_{BLb,ij}) and G(W_{BL,ij}) are the respective conductance of the two complementary primary memory components;
each latent variable is encoded using two complementary secondary memory components connected to a common sense line;
each latent variable depends on respective conductances of the two complementary secondary memory components;
each latent variable verifies the following equation:

mᵢⱼ=G(M_{BLb,ij})−G(M_{BL,ij})

where mᵢⱼ represents a respective latent variable, and

G(M_{BLb,ij}) and G(M_{BL,ij}) are the respective conductance of the two complementary secondary memory components;
during the weight update step, each latent variable is modified depending on the sign of the respective product,

each latent variable being preferably increased if the respective product is positive, and conversely decreased if said product is negative;
during the weight update step, each binary weight is updated according to an algorithm including following first and second cases:

first case: if G(W_{BLb,ij})<G(W_{BL,ij}) and G(M_{BLb,ij})>G(M_{BL,ij})+Threshold1 then switch to G(W_{BLb,ij})>G(W_{BL,ij}),

preferably by increasing G(W_{BLb,ij})

Threshold1 being preferably equal to (G(W_{BLb,ij})−G(W_{BL,ij}));

second case: if G(W_{BL,ij})<G(W_{BLb,ij}) and G(M_{BL,ij})>G(M_{BLb,ij})+Threshold2 then switch to G(W_{BL,ij})>G(W_{BLb,ij}),

preferably by increasing G(W_{BL,ij}),

Threshold2 being preferably equal to (G(W_{BL,ij})−G(W_{BLb,ij})));

where G(W_{BLb,ij}) and G(W_{BL,ij}) are the respective conductance of the two complementary primary memory components,

G(M_{BLb,ij}) and G(M_{BL,ij}) are the respective conductance of the two complementary secondary memory components, and

Threshold1, Threshold2 are respective thresholds;

the algorithm preferably consisting of said first and second cases;
increasing the conductance of a respective memory component is obtained by applying a SET pulse to the corresponding phase-change memory device;

the SET pulse being preferably a low current pulse with a long duration, and

a RESET pulse being a high current pulse with a short duration.

The subject-matter of the invention is also an electronic circuit for operating a binarized neural network, the binarized neural network including input neurons for receiving input values, output neurons for delivering output values and intermediate neurons between the input and output neurons, a respective binary weight being associated to each connection between two respective neurons, a training of the binarized neural network comprising:
a forward pass including calculating an output vector by applying the binarized neural network on an input vector in a forward direction from the input neurons to the output neurons;
a backward pass including computing an error vector between the calculated output vector and a learning output vector and calculating a new value of the input vector by applying the binarized neural network on the error vector in a backward direction from the output neurons to the input neurons; and
a weight update including, for each binary weight, computing a product by multiplying a respective element of the error vector with a respective element of the new value of the input vector; modifying a latent variable depending on the product; and updating the respective binary weight as a function of the latent variable with respect to a threshold;

the electronic circuit comprising a plurality of memory cells, each memory cell being associated to a respective binary weight, each memory cell including at least one primary memory component for encoding the respective binary weight;

each memory cell further including at least one secondary memory component for encoding a respective latent variable, each latent variable being used for updating the respective binary weight, each secondary memory component having a characteristic subject to a time drift,

each one of the primary and secondary memory components being a phase-change memory device.

According to another advantageous aspect of the invention, the electronic circuit further comprises:
a plurality of primary word lines to command the primary memory components;
a plurality of secondary word lines to command the secondary memory components;
a plurality of sense lines and bit lines connected to the memory cells;
a first control module to control the primary word lines, the secondary word lines and the sense lines; and
a second control module to control the bit lines;

a respective sense line being preferably connected to both primary and secondary memory components of a corresponding memory cell;

a respective bit line being preferably connected to both primary and secondary memory components of a corresponding memory cell.

### BRIEF DESCRIPTION OF THE DRAWINGS

The invention will be better understood upon reading of the following description, which is given solely by way of example and with reference to the appended drawings, wherein:

FIG. 1 is a schematic view of an electronic circuit, according to the invention, for operating a binarized neural network, in particular for training said binarized neural network, the electronic circuit comprising a plurality of memory cells, each memory cell being associated to a respective binary weight of the binarized neural network, only two successive layers of the binarized neural network being shown on this figure;

FIG. 2 is a schematic view of a respective memory cell of FIG. 1, and of a pre-charge sense amplifier for operating the memory cell;

FIG. 3 is a flowchart of a process for operating the binarized neural network, the process including a training phase wherein a method according to the invention for training the binarized neural network is implemented, and then an inference phase wherein the trained binarized neural network is used to compute output values;

FIG. 4 is a set of curves representing a progressive increase of a conductance of memory components included in the memory cells of FIGS. 1 and 2, said conductance increase being obtained with multiple successive applications of a SET pulse; and

FIG. 5 is a set of curves showing alternating increases and decreases over time in the conductance of said memory components included in the memory cells of FIGS. 1 and 2, the conductance increases being obtained with SET pulses and the conductance decreases being due to time drifts.

### DETAILED DESCRIPTION

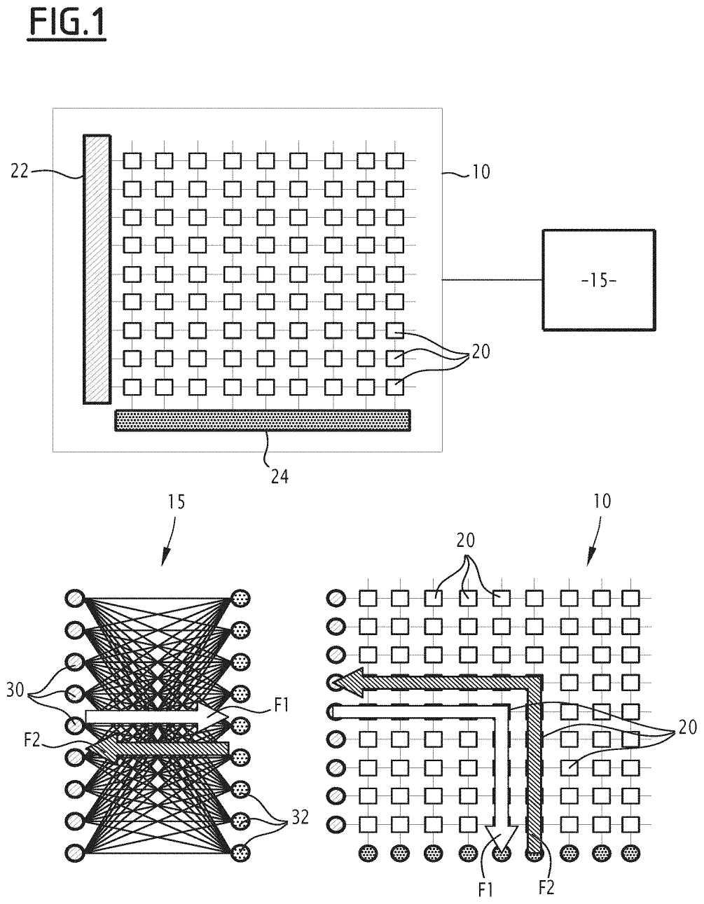

In FIG. 1, an electronic circuit 10 is configured for operating a binarized neural network 15, also called BNN. In particular, the electronic circuit 10 is configured for training, i.e. for learning, the binarized neural network 15 and then configured for using the trained binarized neural network 15 to compute new output values from new input values. In other words, the electronic circuit 10 is preferably configured for both training and inference of the binarized neural network 15.

In this description, the terms “training” and “learning” are considered to be equivalent, i.e. to have the same meaning, and are therefore used interchangeably.

The electronic circuit 10 comprises a plurality of memory cells 20, each memory cell 20 being associated to a respective binary weight of the binarized neural network 15. In the example of FIG. 1, the memory cells 20 are arranged in the form of a matrix, and the binary weights are also denoted W_{bin,ij}, where i is an index related to the columns of the matrix and j is an index related to the rows of said matrix.

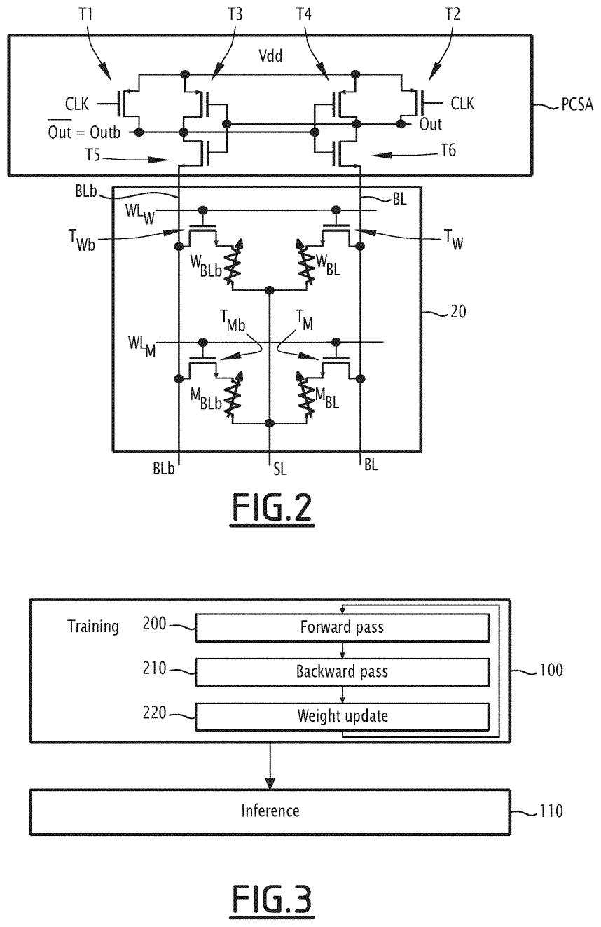

In the example of FIGS. 1 and 2, the electronic circuit 10 comprises a plurality of primary word lines WL_{Wj}, a plurality of secondary word lines WL_{Mj} and a plurality of sense lines SLⱼ and bit lines BLbᵢ, BLᵢ connected to the memory cells 20. In the example of FIGS. 1 and 2, to each memory cell 20 is connected a pair of a respective primary word line WL_{Wj} and a respective secondary word line WL_{Mj}, a respective sense line SLⱼ and a pair of complementary bit lines BLbᵢ, BLᵢ, namely a first bit line BLbᵢ and a second bit line BLᵢ. In the example of FIG. 2, the primary word lines, the secondary word lines, the sense lines, the first bit lines and the second bit lines are respectively denoted WL_{W}, WL_{M}, SL and BLb, BL, i.e. without reciting the indexes i and j for sake of simplicity of the drawings.

In addition, the electronic circuit 10 comprises a plurality of pre-charge sense amplifiers PCSA, typically a pre-charge sense amplifier PCSA for each column of the matrix, in particular a pre-charge sense amplifier PCSA for each pair of complementary bit lines BLbᵢ, BLᵢ. As know per se, for example from the aforementioned article “Digital Biologically Plausible Implementation of Binarized Neural Networks with Differential Hafnium Oxide Resistive Memory Arrays” from T. Hirtzlin et al, the pre-charge sense amplifiers PCSA are configured for being used during readout operations of the memory cells 20. The pre-charge sense amplifiers PCSA are highly energy-efficient due to their operation in two phases, namely a pre-charge phase and a discharge phase, avoiding any direct path between a supply voltage and a ground. The high-energy efficiency is mainly due to the high speed of computation, the current flowing in the memory cells 20 during a very short amount of time, typically during some nanoseconds or some tens of nanoseconds. The operation of the pre-charge sense amplifier PCSA will be explained in more detail in a subsequent section of the description.

In addition, the electronic circuit 10 comprises a first control module 22 to control the primary word lines WL_{Wj}, the secondary word lines WL_{Mj} and the sense lines SLⱼ; and a second control module 24 to control the first and second bit lines BLbᵢ, BLᵢ. Preferably, the first and second control modules 22, 24 allow to carry out a fully digital control of the primary word lines WL_{Wj}, the secondary word lines WL_{Mj} and the sense lines SLⱼ, and respectively of the first and second bit lines BLbᵢ, BLᵢ.

The binarized neural network 15 includes input neurons for receiving input values, output neurons for delivering output values and intermediate neurons between the input and output neurons, a respective binary weight W_{bin,ij} being associated to each connection between two respective neurons.

In the example of FIG. 1, for sake of simplicity of the drawings, only two successive layers of the binarized neural network 15 are shown, namely a first layer with first neurons 30 and a second layer with second neurons 32, with multiple neuron connections between the first and second neurons 30, 32 and a respective binary weight W_{bin,ij} associated to each neuron connection between two respective neurons 30, 32. The skilled person will understand that the first layer with first neurons 30 and the second layer with second neurons 32 are representative of any pair of successive layers of the binarized neural network 15.

As known per se, a training of the binarized neural network 15 comprises a forward pass including calculating an output vector W_{bin}.X by applying the binarized neural network 15 on an input vector X in a forward direction from the input neurons to the output neurons, symbolized by an arrow F1 in FIG. 1 from first neurons 30 to second neurons 32.

The training of the binarized neural network 15 further comprises a backward pass including computing an error vector dY between the calculated output vector W_{bin}.X and a learning output vector Y_{pred} and then calculating a new value of the input vector X by applying the binarized neural network 15 on the error vector dY in a backward direction from the output neurons to the input neurons, symbolized by an arrow F2 in FIG. 1 from second neurons 32 to first neurons 30.

The training of the binarized neural network 15 finally comprises a weight update including, for each binary weight W_{bin,ij}, computing a product g_{t,ij} by multiplying a respective element dYᵢ of the error vector with a respective element Xⱼ of the new value of the input vector; then modifying a latent variable mᵢⱼ depending on the product g_{t,ij}; and lastly updating the respective binary weight W_{bin,ij} as a function of the latent variable mᵢⱼ with respect to a threshold.

Each memory cell 20 includes at least one primary memory component W_{BLb,ij}, W_{BL,ij} for encoding the respective binary weight W_{bin,ij}.

In optional addition, each memory cell 20 includes two complementary primary memory components W_{BLb,ij}, W_{BL,ij}, namely a first primary memory component W_{BLb,ij} and a second primary memory component W_{BL,ij}, for encoding the respective binary weight W_{bin,ij}, these two complementary primary memory components W_{BLb,ij}, W_{BL,ij} being connected to a common sense line SLⱼ.

According to the invention, each memory cell 20 further includes at least one secondary memory component M_{BLb,ij}, M_{BL,ij} for encoding a respective latent variable mᵢⱼ, each latent variable mᵢⱼ being used for updating the respective binary weight W_{bin,ij}.

In optional addition, each memory cell 20 includes two complementary secondary memory components M_{BLb,ij}, M_{BL,ij}, namely a first secondary memory component M_{BLb,ij}, and a second secondary memory component M_{BL,ij}, for encoding the respective latent variable mᵢⱼ, these two complementary secondary memory components M_{BLb,ij}, M_{BL,ij} being connected to the common sense line SLⱼ.

Each memory cell 20 includes for example two complementary primary memory components W_{BLb,ij}, W_{BL,ij}, two complementary secondary memory components M_{BLb,ij}, M_{BL,ij} and four switching components T_{Wb,ij}, T_{W,ij}, T_{Mb,ij}, T_{M,ij}, each switching component T_{Wb,ij}, T_{W,ij}, T_{Mb,ij}, T_{M,ij} being connected to a respective memory component W_{BLb,ij}, W_{BL,ij}, M_{BLb,ij}, M_{BL,ij}, as shown in FIG. 2. Accordingly, each memory cell 20 includes a first primary switching component T_{Wb,ij} connected to the first primary memory component W_{BLb,ij} and a second primary switching component T_{W,ij} connected to the second primary memory component W_{BL,ij}. Similarly, each memory cell 20 includes a first secondary switching component T_{Mb,ij} connected to the first secondary memory component M_{BLb,ij} and a second secondary switching component T_{M,ij} connected to the second secondary memory component M_{BL,ij}.

In the example of FIG. 2, each switching component T_{Wb,ij}, T_{W,ij}, T_{Mb,ij}, T_{M,ij} is a transistor, such a FET (for Field-Effect Transistor), in particular a MOSFET for (Metal-Oxide-Semiconductor Field-Effect Transistor), also known as a MOS (for Metal-Oxide-Silicon) transistor, for example a NMOS transistor.

In the example of FIG. 2, each switching component T_{Wb,ij}, T_{W,ij}, T_{Mb,ij}, T_{M,ij} in form of a respective transistor has a gate electrode, a source electrode and a drain electrode; and is connected via its gate electrode to a respective word line WL_{Wj}, WL_{Mj}, via its drain electrode to a respective bit line BLbᵢ, BLᵢ and via its source electrode to one of the two electrodes of a respective memory component W_{BLb,ij}, W_{BL,ij}, M_{BLb,ij}, M_{BL,ij}, the other electrode of said memory component W_{BLb,ij}, W_{BL,ij}, M_{BLb,ij}, M_{BL,ij} being connected to a respective sense line SLⱼ.

In other words, a respective sense line SLⱼ is preferably connected to both primary W_{BLb,ij}, W_{BL,ij} and secondary M_{BLb,ij}, M_{BL,ij} memory components of a corresponding memory cell 20. A respective bit line BLbᵢ, BLᵢ is preferably connected to both primary W_{BLb,ij}, W_{BL,ij} and secondary M_{BLb,ij}, M_{BL,ij} memory components of a corresponding memory cell 20. In particular, the first bit line BLbᵢ is preferably connected to both first primary W_{BLb,ij} and first secondary M_{BLb,ij} memory components of a respective memory cell 20; and the second bit line BLᵢ is preferably connected to both second primary W_{BL,ij} and second secondary M_{BL,ij} memory components of this respective memory cell 20.

In the example of FIG. 2, each memory cell 20 is configured in a 4T4R structure wherein the four switching components, such as the four transistors T_{Wb,ij}, T_{W,ij}, T_{Mb,ij}, T_{M,ij}, correspond to the “4T” and the four memory component W_{BLb,ij}, W_{BL,ij}, M_{BLb,ij}, M_{BL,ij} correspond to the “4R”.

Each pre-charge sense amplifier PCSA includes for example six switching components T1, T2, T3, T4, T5, T6, namely a first switching component T1, a second switching component T2, a third switching component T3, a fourth switching component T4, a fifth switching component T5 and a sixth switching component T6, as shown in FIG. 2. Each switching component T1, T2, T3, T4, T5, T6 has two conduction electrodes and a control electrode. In the example of FIG. 2, each switching component T1, T2, T3, T4, T5, T6 is a transistor, such a FET, in particular a MOSFET or MOS transistor. Accordingly, the two conduction electrodes are a source electrode and a drain electrode; and the control electrode is a gate electrode.

Each pre-charge sense amplifier PCSA is connected to a supply line Vdd; to a clock line CLK; and two complementary output lines, namely a first output line Out and a second output line Outb complementary to the first output line Out.

In the example of FIG. 2, the first switching component T1 is connected via its conduction electrodes between the supply line Vdd and the second output line Outb and via its control electrode to the clock line CLK. The second switching component T2 is connected via its conduction electrodes between the supply line Vdd and the first output line Out and via its control electrode to the clock line CLK. In the example of FIG. 2, the first and second switching components T1, T2 are PMOS, with their source electrode connected to the supply line Vdd.

In the example of FIG. 2, the third switching component T3 is connected via its conduction electrodes between the supply line Vdd and the second output line Outb and via its control electrode to the first output line Out. The fourth switching component T4 is connected via its conduction electrodes between the supply line Vdd and the first output line Out and via its control electrode to the second output line Outb. In the example of FIG. 2, the third and fourth switching components T3, T4 are PMOS, with their source electrode connected to the supply line Vdd.

In the example of FIG. 2, the fifth switching component T5 is connected via its conduction electrodes between the second output line Outb and the first bit line BLb and via its control electrode to the first output line Out. The sixth switching component T6 is connected via its conduction electrodes between the first output line Out and the second bit line BL and via its control electrode to the second output line Outb. In the example of FIG. 2, the fifth and sixth switching components T5, T6 are NMOS, with their source electrode connected to the respective bit line BL, BLb.

In the example of FIG. 2 and in a conventional manner, the electric connection between an electrode and a respective line is symbolized by a dot; and the crossing of two lines without a dot at the intersection of these two lines corresponds to an absence of electrical connection between these two lines.

In the example of FIG. 2, the primary memory components and respectively the secondary memory components are denoted W_{BLb}, W_{BL} and respectively M_{BLb}, M_{BL}, i.e.

without reciting the indexes i and j for sake of simplicity of the drawings. Similarly, the primary switching components and respectively the secondary switching components are denoted T_{Wb}, T_{W} and respectively T_{Mb}, T_{M}, i.e. without reciting the indexes i and j for sake of simplicity of the drawings.

The first control module 22 is configured to control the primary word lines WL_{Wj}, the secondary word lines WL_{Mj} and the sense lines SLⱼ. As previously described, the primary word lines WL_{Wj} are configured for controlling the primary memory components W_{BLb,ij}, W_{BL,ij}; and the secondary word lines WL_{Mj} are configured for controlling the secondary memory components M_{BLb,ij}, M_{BL,ij}.

The second control module 24 is configured to control the first and second bit lines BLbᵢ, BLᵢ.

The first control module 22 and the second control module 24 are configured to be piloted in a coordinated manner, known per se, for example with the RAM (for Random Access Memory) technology, so as to operate the memory cells 20, in particular the primary memory components W_{BLb,ij}, W_{BL,ij} and/or the secondary memory components M_{BLb,ij}, M_{BL,ij}, according to well-known memory operation states, namely a hold state for keeping a value contained in a respective memory component W_{BLb,ij}, W_{BL,ij}, M_{BLb,ij}, M_{BL,ij}, a write state for writing a new value in a respective memory component W_{BLb,ij}, W_{BL,ij}, M_{BLb,ij}, M_{BL,ij}, and a read state for reading the value of a respective memory component W_{BLb,ij}, W_{BL,ij}, M_{BLb,ij}, M_{BL,ij}.

Each primary memory component W_{BLb,ij}, W_{BL,ij} has a characteristic subject to a time drift. The characteristic subject to the time drift for each primary memory component W_{BLb,ij}, W_{BL,ij} is for example a conductance, respectively denoted G(W_{BLb,ij}), G(W_{BL,ij}).

Each primary memory component W_{BLb,ij}, W_{BL,ij} is typically a resistive memory device. Each primary memory component W_{BLb,ij}, W_{BL,ij} is for example a phase-change memory device. Alternatively, each primary memory component W_{BLb,ij}, W_{BL,ij} is an hafnium-oxide resistive random-access memory device, also called hafnium-oxide RRAM device or OxRAM device; a conductive bridging random-access memory device, also called CBRAM device; a magnetic random-access memory device, also called MRAM device; or a ferroelectric memory device.

Each secondary memory component M_{BLb,ij}, M_{BL,ij} has a characteristic subject to a time drift. The characteristic subject to the time drift secondary memory component M_{BLb,ij}, M_{BL,ij} is for example a conductance, respectively denoted, G(M_{BLb,ij}), G(M_{BL,ij}).

Each secondary memory component M_{BLb,ij}, M_{BL,ij} is preferably a phase-change memory device. Alternatively, each secondary memory component M_{BLb,ij}, M_{BL,ij} is an hafnium-oxide resistive random-access memory device, also called hafnium-oxide RRAM device or OxRAM device; or a volatile conductive bridging random-access memory device, also called volatile CBRAM device.

The phase-change memory device is also known as PCM (for Phase Change Memory), PRAM (for Phase-change Random Access Memory), PCRAM (for Phase Change RAM), OUM (for Ovonic Unified Memory) and C-RAM or CRAM (for Chalcogenide Random Access Memory) device. The phase-change memory device is a type of non-volatile random-access memory.

The phase-change memory devices generally exploit the unique behavior of chalcogenide materials. For some phase-change memory devices, heat produced by the flow of an electric current through a heating element generally made of titanium nitride was used to either quickly heat and quench the chalcogenide material, making it amorphous, or to hold it in its crystallization temperature range for some time, thereby switching it to a crystalline state.

The phase-change memory device also has the ability to achieve a number of distinct intermediary states, thereby having the ability to hold multiple bits in a single cell.

The operation of the electronic circuit 10 according to the invention will now be explained in view of FIG. 3 representing a flowchart of a process for operating the binarized neural network 15 with the electronic circuit 10, the process including a training phase 100 wherein a method according to the invention for training the binarized neural network 15 is implemented, and then an inference phase 110 wherein the trained binarized neural network 15 is used to compute output values.

The training phase 100 includes a forward pass step 200, followed by a backward pass step 210 and then a weight update step 220.

The forward pass step 200, the backward pass step 210 and the weight update step 220 are carried out an iterative manner, a new forward pass step 200 being carried out after a previous weight update step 220, until the binarized neural network 15 is properly trained, i.e. until a solution is found to a loss function between an output vector W_{bin}.X calculated by applying the binarized neural network 15 on the input vector X and a learning output vector Y_{pred}, said solution minimizing the loss function corresponding to an optimal binary weight vector Y_{ref}.

During the forward pass step 200, the electronic circuit 10 calculates the output vector W_{bin}.X by applying the binarized neural network 15 on the input vector X in the forward direction F1 from the input neurons to the output neurons, in particular from first neurons 30 to second neurons 32.

When a classical neural network is applied to an input vector so as to calculate an output vector, each neuron receives input values corresponding to the output values of the neurons of a previous layer aⱼ and performs a weighted sum ΣⱼWᵢⱼ.aⱼ, and then it applies a non-linear function f to the result of this weighted sum.

With the binarized neural network 15, the weighted sum is obtained by performing the following equation:

aᵢ=sign[popcountⱼ XNOR(W_{bin,ij},aⱼ)−Tᵢ] (1)

where aᵢ represent the output values calculated with the neurons of the current layer;

W_{bin,ij} represents the respective binary weights for the neurons of the current layer;

aⱼ represent the input values for the neurons of the current layer, i.e. the output values of the neurons of the previous layer;

XNOR is a function returning logical complement of the Exclusive OR;

popcount is a function that counts the number of 1 in a series of bits;

Tᵢ is a predefined threshold; and

sign is a sign function applied to an operand and issuing the value 1 if the operand is positive and −1 if the operand is negative.

In other words, the product becomes a logic gate XNOR between the binary weight W_{bin} and the presynaptic neuron activation aj, the sum becomes the popcount function, then a comparison with the threshold Tᵢ, gives the binary output 1 or −1 if the value is respectively above or below this threshold. Preferably, this comparison gives an instruction if the binary output value has to be changed or not.

After the forward pass step 200, the electronic circuit 10 then computes the error vector dY between the calculated output vector W_{bin}.X and the learning output vector Y_{pred} and further calculates, during the next backward pass step 210, the new value of the input vector X by applying the binarized neural network 15 on the error vector dY in the backward direction F2 from the output neurons to the input neurons, in particular from second neurons 32 to first neurons 30.

Further to the backward pass step 210, the electronic circuit 10 finally updates the value of each each binary weight W_{bin,ij} during the weight update step 220.

During this weight update step 220, the electronic circuit 10 first computes the product g_{t,ij} by multiplying a respective element dY, of the error vector with a respective element Xⱼ of the new value of the input vector, then modifies the latent variable mᵢⱼ depending on the product g_{t,ij}; and lastly updates the respective binary weight W_{bin,ij} as a function of the latent variable mᵢⱼ with respect to a respective threshold.

During the training phase 100, and also during the subsequent inference phase 110, each binary weight W_{bin,ij} is preferably encoded using the two complementary primary memory components W_{BLb,ij}, W_{BL,ij}.

In this example, each binary weight W_{bin,ij} typically depends on respective conductances G(W_{BLb,ij}), G(W_{BL,ij}) of the two complementary primary memory components W_{BLb,ij}, W_{BL,ij}.

Each binary weight W_{bin,ij} verifies typically the following equation:

$$Wbin , ij = sign ( \frac{G ( {W}_{BLb , ij} )}{G ( {W}_{BL , ij} )} ) \qquad ( 2 )$$

where W_{bin,ij} represents a respective binary weight,

sign is a sign function applied to an operand and issuing the value 1 if the operand is positive and −1 if the operand is negative, and

G(W_{BLb,ij}) and G(W_{BL,ij}) are the respective conductance of the two complementary primary memory components W_{BLb,ij}, W_{BL,ij}.

According to this example with the two complementary primary memory components W_{BLb,ij}, W_{BL,ij}, for obtaining a binary weight W_{bin,ij} value, first, a clock signal on the clock line CLK is set to the ground in the respective pre-charge sense amplifier PCSA and the sense line SLⱼ to the supply voltage, which precharges the two selected complementary primary memory components W_{BLb,ij}, W_{BL,ij} as well as a comparing latch formed by the third and fourth switching components T3, T4 at the same voltage.

Second, the clock signal on the clock line CLK is set to the supply voltage, the sense line SLⱼ is set to the ground and the voltages on the complementary primary memory components W_{BLb,ij}, W_{BL,ij} are discharged to the ground through the sense line SLⱼ. The branch, i.e. the first bit line BLbᵢ or the second bit line BLᵢ, with the lowest resistance discharges faster and causes its associated inverter output, i.e. the fifth T5 or sixth T6 switching component, to discharge to the ground, which latches the complementary inverter output, i.e. the sixth T6 or fifth T5 switching component, to the supply voltage. The two output voltages in the two complementary output lines Out, Outb therefore represent the comparison of the two complementary conductance values G(W_{BLb,ij}), G(W_{BL,ij}).

During the forward pass step 200 and the backward pass step 210, the electronic circuit 10, in particular the first control module 22, only selects the word line corresponding to the binary weight W_{bin,ij}, i.e. the respective primary word line WL_{Wj}. When this word line is the only one selected and as described above, the pre-charge sense amplifier PCSA outputs a binary output value corresponding to the binary weight W_{bin,ij} which is usable to perform forward and backward calculations.

Then, during the weight update step 220, this time the electronic circuit 10, in particular the first control module 22, activates the respective secondary word line WL_{Mj} to update the conductances G(M_{BLb,ij}), G(M_{BL,ij}) of the two complementary secondary memory components M_{BLb,ij}, M_{BL,ij}, preferably according to the sign of the respective product g_{t,ij}.

In addition, during the weight update step 220, each latent variable mᵢⱼ is preferably encoded using the two complementary secondary memory components M_{BLb,ij}, M_{BL,ij}.

In this example, each latent variable mᵢⱼ depends on respective conductances G(M_{BLb,ij}), G(M_{BL,ij}) of the two complementary secondary memory components M_{BLb,ij}, M_{BL,ij}.

Each latent variable mᵢⱼ verifies for example the following equation:

mᵢⱼ=G(M_{BLb,ij})−G(M_{BL,ij}) (3)

where mᵢⱼ represents a respective latent variable, and

G(M_{BLb,ij}) and G(M_{BL,ij}) are the respective conductance of the two complementary secondary memory components M_{BLb,ij}, M_{BL,ij}.

During the weight update step 220, each latent variable mᵢⱼ is preferably modified depending on the sign of the respective product g_{t,ij}. Each latent variable mᵢⱼ is for example increased if the respective product g_{t,ij} is positive, and conversely decreased if said product g_{t,ij} is negative.

At the end of the weight update step 220, the electronic circuit 10, in particular the first and second control modules 22, 24, perform a reading to compare a (G(M_{BLb,ij})−G(M_{BL,ij})) conductance difference with a threshold Threshold1, Threshold2 by activating both respective primary word line WL_{Wj} and respective secondary word line WL_{Mj}. When carrying out this double word line activation, the value read by the pre-charge amplifier PCSA is different from the stored binary weight W_{bin,ij} if and only if the difference in conductance is higher than the threshold Threshold1, Threshold2.

Preferably, the threshold Threshold1, Threshold2 is directly coded in the binary weight W_{bin,ij}, i.e. with the respective conductances G(W_{BLb,ij}), G(W_{BL,ij}) of the two complementary primary memory components W_{BLb,ij}, W_{BL,ij}. Accordingly, a first threshold Threshold1 is preferably equal to (G(W_{BLb,ij})−G(W_{BL,ij})); and a second threshold Threshold2 is preferably equal to (G(W_{BL,ij})−G(W_{BLb,ij})).

During the weight update step 220, each binary weight W_{bin,ij} is then updated for example according to an algorithm including following first and second cases:

first case: if G(W_{BLb,ij})<G(W_{BL,ij}) and G(M_{BLb,ij})>G(M_{BL,ij})+Threshold1 then switch to G(W_{BLb,ij})>G(W_{BL,ij}),

second case: if G(W_{BL,ij})<G(W_{BLb,ij}) and G(M_{BL,ij})>G(M_{BLb,ij})+Threshold2 then switch to G(W_{BL,ij})>G(W_{BLb,ij}),
where G(W_{BLb,ij}) and G(W_{BL,ij}) are the respective conductance of the two complementary primary memory components W_{BLb,ij}, W_{BL,ij},
G(M_{BLb,ij}) and G(M_{BL,ij}) are the respective conductance of the two complementary secondary memory components M_{BLb,ij}, M_{BL,ij}, and
Threshold1, Threshold2 are respectively the first and second thresholds.

The aforementioned algorithm to update each binary weight W_{bin,ij} preferably consists of said first and second cases.

By example, for implementing the aforementioned algorithm, the electronic circuit 10, in particular the first and second control modules 22, 24, perform a first read to detect if G(W_{BLb,ij})<G(W_{BL,ij}) determining therefore that the first case applies or else if G(W_{BL,ij})<G(W_{BLb,ij}) determining therefore that the second case applies. The first read is performed by selecting only the respective primary word line WL_{Wj}.

Then, the electronic circuit 10, in particular the first and second control modules 22, 24, perform a second read to detect if G(M_{BLb,ij})>G(M_{BL,ij})+Threshold1, preferably if G(M_{BLb,ij})>G(M_{BL,ij})+G(W_{BLb,ij})−G(W_{BL,ij}), if the first case was determined further to the first read; or else to detect if G(M_{BL,ij})>G(M_{BLb,ij})+Threshold2, preferably if G(M_{BL,ij})>G(M_{BLb,ij}) +G(W_{BL,ij})−G(W_{BLb,ij}), if the second case was determined further to the first read. The second read is performed by selecting both the respective primary WL_{Wj} and secondary WL_{Mj} word lines.

For performing each one of the first read and the second read, the following actions are carried out, the only difference between the first read and the second read being the difference in the word line selection, namely only the respective primary word line WL_{Wj} for the first read, while both the respective primary WL_{Wj} and secondary WL_{Mj} word lines for the second read.

Accordingly, for a given read among the first read and the second read, firstly, the sense line SLⱼ is charged at supply voltage and the clock signal on the clock line CLK is set to the ground. With the clock signal on the clock line CLK set to the ground, the first and second switching components T1, T2, typically PMOS transistors, are turned on, and the supply voltage is applied at the two output voltages in the two complementary output lines Out, Outb of the latch.

Secondly, the voltages are discharged at the primary W_{BLb,ij}, W_{BL,ij} and secondary M_{BLb,ij}, M_{BL,ij} memory components, to the ground through the sense line SLⱼ. This is achieved by setting the clock signal on the clock line CLK to the supply voltage and the sense line SLⱼ to the ground. Considering that the latches of the pre-charge amplifier PCSA, i.e. the two complementary output lines Out, Outb, are both at supply voltages, the fifth and sixth switching components T5, T6, typically NMOS transistors, are turned on, letting current flow through the branches of the primary memory components W_{BLb,ij}, W_{BL,ij} when only the respective primary word line WL_{Wj} is activated; or else through the branches of the primary W_{BLb,ij}, W_{BL,ij} and secondary M_{BLb,ij}, M_{BL,ij} memory components when both the respective primary WL_{Wj} and secondary WL_{Mj} word lines are activated. Then, since the memory components W_{BLb,ij}, W_{BL,ij}, M_{BLb,ij}, M_{BL,ij} have different resistances, the discharge speed is not the same in each of the branches, i.e. in the first bit line BLbᵢ and in the second bit line BLᵢ. Because the current is greater in the low-resistance branch, the low resistance branch discharges faster. The state of the branch of the latch with low resistance will decrease faster than the other with high resistance; this disequilibrium will be amplified until the state of the high current branch discharges to the ground controlling the PMOS transistor in the complementary branch. Therefore, the PMOS transistor of the other branch is charged to Vdd.

The state of the latch, i.e. of the respective complementary output lines Out, Outb, therefore allows comparing G(W_{BLb,ij}) with G(W_{BL,ij}) in case of the first read; or else comparing the sum (G(W_{BLb,ij})+G(M_{BLb,ij})) with the sum (G(W_{BL,ij})+G(M_{BL,ij})) in case of the second read, i.e. carrying out the comparison G(M_{BLb,ij})>G(M_{BL,ij})+Threshold1 with Threshold1 equal to (G(W_{BLb,ij})−G(W_{BL,ij})) or the comparison G(M_{BL,ij})>G(M_{BLb,ij})+Threshold2 with Threshold2 equal to (G(W_{BL,ij})−G(W_{BLb,ij})).

The electronic circuit 10, in particular the first and second control modules 22, 24, preferably perform these operations row by row, so that only one bit register per column of the matrix is required.

With the aforementioned algorithm, In the first case, if a switch to G(W_{BLb,ij})>G(W_{BL,ij}) is commanded, this switch from G(W_{BLb,ij})<G(W_{BL,ij}) to G(W_{BLb,ij})>G(W_{BL,ij}) is typically carried out by increasing the conductance G(W_{BLb,ij}).

Similarly, in the second case, if a switch to G(W_{BL,ij})>G(W_{BLb,ij}) is commanded, this switch from G(W_{BL,ij})<G(W_{BLb,ij}) to G(W_{BL,ij})>G(W_{BLb,ij}) is typically carried out by increasing the conductance G(W_{BL,ij}).

In optional addition, when the primary memory components W_{BLb,ij}, W_{BL,ij}, respectively the secondary memory components M_{BLb,ij}, M_{BL,ij}, are phase-change memory devices, increasing the conductance G(W_{BLb,ij}), G(W_{BL,ij}), G(M_{BLb,ij}) G(M_{BL,ij}) of a respective memory component W_{BLb,ij}, W_{BL,ij}, M_{BLb,ij}, M_{BL,ij} is obtained by applying a SET pulse to the corresponding phase-change memory device.

In further optional addition, the switch from G(W_{BLb,ij})<G(W_{BL,ij}) to G(W_{BLb,ij})>G(W_{BL,ij}) is preferably obtained by applying the SET pulse to the memory component W_{BLb,ij} and a RESET pulse to the memory component W_{BL,ij}. Similarly, the switch from G(W_{BL,ij})<(G(W_{BLb,ij}) to G(W_{BL,ij})>G(W_{BLb,ij}) is preferably obtained by applying the SET pulse to the memory component W_{BL,ij} and the RESET pulse to the memory component W_{BLb,ij}.

As known per se, the SET pulse is typically a low current pulse with a long duration, and the RESET pulse is typically a high current pulse with a short duration.

As an example, to apply the SET pulse to a respective memory component W_{BLb,ij}, W_{BL,ij}, M_{BLb,ij}, M_{BL,ij}, in particular to a PCM device, the corresponding bit line BLbⱼ, BLⱼ is set to the ground, while the sense line SLᵢ is set to a predefined SET voltage, typically 1.2 V, for a progressive set behavior with a small pulse duration, typically comprised between 100 ns and 200 ns. The SET pulse applied to the PCM device includes for example a first ramp lasting about 100 ns with increasing value from 0V to 1.2V, a second ramp lasting about 20 ns with constant value equal to 1.2V, and a third ramp lasting about 20 ns with decreasing value from 1.2V to 0V.

Alternatively, when the respective memory component W_{BLb,ij}, W_{BL,ij}, M_{BLb,ij}, M_{BL,ij}, is an OxRAM device, to apply the SET pulse, the corresponding bit line BLbⱼ, BLⱼ is set to the ground, while the sense line SLᵢ is set to the predefined SET voltage, typically 2 V for OxRAM. The corresponding word line WL_{Wj}, WL_{Mj} is set to a voltage chosen to limit the current to a compliance value, ranging from 20 to 200 μA depending on the chosen programming condition.

As a variant, to apply the SET pulse to a respective memory component W_{BLb,ij}, W_{BL,ij}, M_{BLb,ij}, M_{BL,ij}, the corresponding bit line BLbⱼ, BLⱼ is set to the predefined SET voltage, while the sense line SLᵢ is set to the ground.

To apply the RESET pulse to a respective memory component W_{BLb,ij}, W_{BL,ij}, M_{BLb,ij}, M_{BL,ij}, in particular to a PCM device, the corresponding bit line BLbⱼ, BLⱼ is set to the ground, while the sense line SLᵢ is set to a predefined RESET voltage, higher than to the predefined SET voltage, with as shorter duration than for the SET pulse.

As a variant, to apply the RESET pulse to a respective memory component W_{BLb,ij}, W_{BL,ij}, M_{BLb,ij}, M_{BL,ij}, the corresponding bit line BLbⱼ, BLⱼ is set to the predefined RESET voltage, while the sense line SLᵢ is set to the ground.

Alternatively, when the respective memory component W_{BLb,ij}, W_{BL,ij}, M_{BLb,ij}, M_{BL,ij}, is an OxRAM device, to apply the RESET pulse, a voltage of opposite sign needs to be applied to the respective memory component W_{BLb,ij}, W_{BL,ij}, M_{BLb,ij}, M_{BL,ij}, and the current compliance is not needed. The sense line SLᵢ is therefore set to the ground, while the corresponding word line WL_{Wj}, WL_{Mj} is set to a value of 3.3 V, and the corresponding bit line BLbⱼ, BLⱼ is set to a “RESET voltage”, chosen for example between 1.5 V and 2.5 V.

During programming such operations, all bit BLbⱼ, BLⱼ, sense SLᵢ and word WL_{Wj}, WL_{Mj} lines corresponding to non-selected memory component W_{BLb,ij}, W_{BL,ij}, M_{BLb,ij}, M_{BL,ij} are grounded, with the exception of the bit line BLbⱼ, BLⱼ of the complementary memory component W_{BL,ij}, W_{BLb,ij}, M_{BL,ij}, M_{BLb,ij} of the selected memory component W_{BLb,ij}, W_{BL,ij}, M_{BLb,ij}, M_{BL,ij}: this one is programmed to the same voltage as the one applied to the sense line SLᵢ to avoid any disturbing effect on the complementary device.

In addition, the training of the binarized neural network is better if the conductance G(W_{BLb,ij}), G(W_{BL,ij}), G(M_{BLb,ij}), G(M_{BL,ij}) of a respective memory component W_{BLb,ij}, W_{BL,ij}, M_{BLb,ij}, M_{BL,ij} is modified progressively, in particular for the conductance G(M_{BLb,ij}), G(M_{BL,ij}) of the respective secondary memory components M_{BLb,ij}, M_{BL,ij} used to encode the respective latent variable mᵢⱼ.

Such a progressive modification of the conductance G(W_{BLb,ij}), G(W_{BL,ij}), G(M_{BLb,ij}), G(M_{BL,ij}) is for example obtained by applying the same SET pulse at multiple successive time instants, thereby allowing to gradually change the conductance. Even if the SET pulse is in principle longer than the RESET pulse, the applied SET pulse has preferably a relatively short duration, for example a duration comprised between 100 ns and 200 ns.

During this weight update step 220, the electronic circuit 10, in particular via the first and second control modules 22, 24, is therefore configured to carry out the following operations:
a read operation for reading the values of the complementary primary memory components W_{BLb,ij}, W_{BL,ij}, to obtain the binary weight W_{bin,ij} value;
a write operation for writing values into the complementary secondary memory components M_{BLb,ij}, M_{BL,ij}, to encode the latent variable mᵢⱼ, typically according to aforementioned equation (3);
successive read operations, namely the first read and then the second read as described above, to compare the (G(M_{BLb,ij})−G(M_{BL,ij})) conductance difference with the threshold; and

when applicable depending on the result of the previous comparison, a write operation for writing values into the complementary primary memory components W_{BLb,ij}, W_{BL,ij}, to switch from G(W_{BLb,ij})<G(W_{BL,ij}) to G(W_{BLb,ij})>G(W_{BL,ij}), or else to switch from G(W_{BL,ij})<G(W_{BLb,ij}) to G(W_{BL,ij})>G(W_{BLb,ij}), so as to update the binary weight W_{bin,ij} value if necessary.

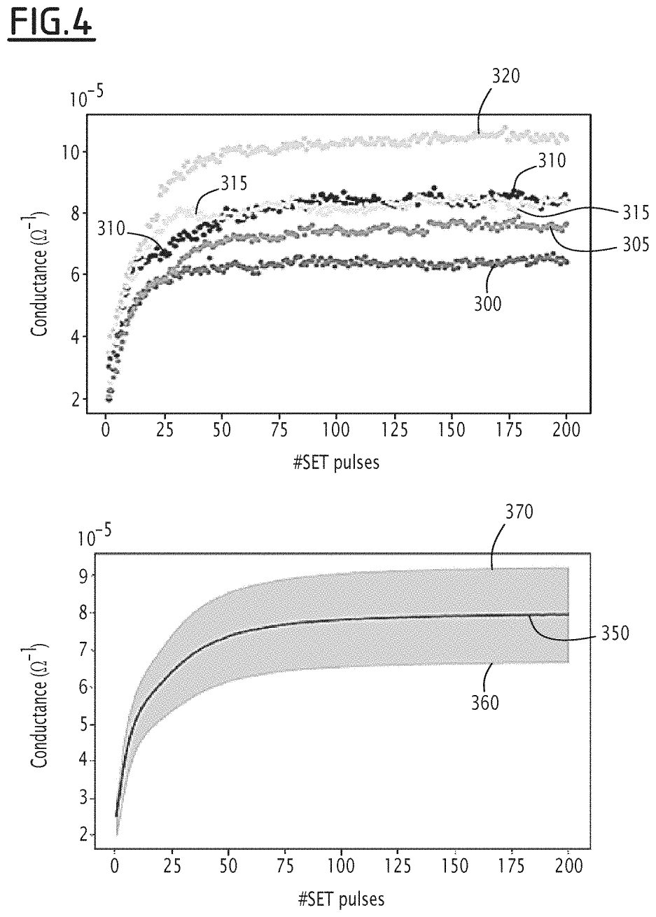

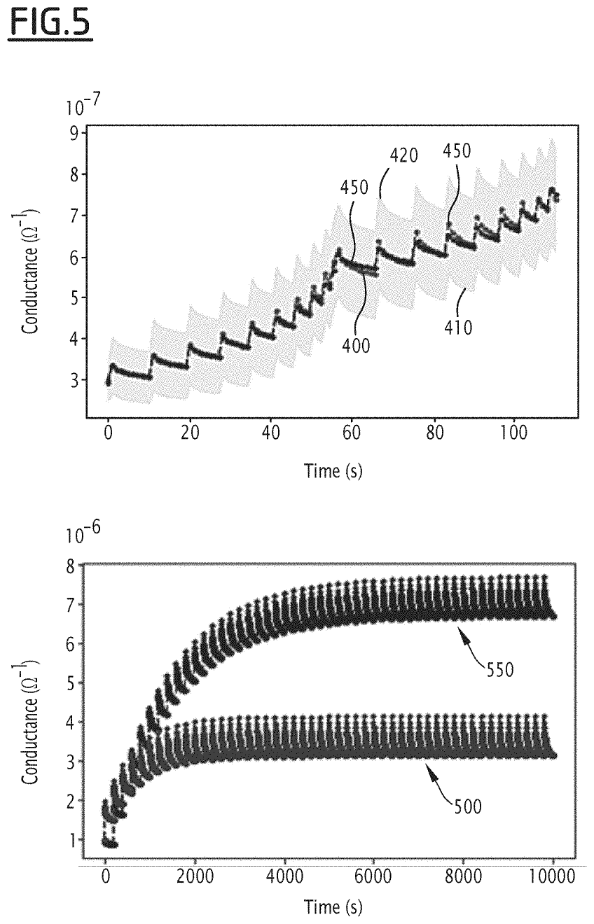

As shown in FIGS. 4 and 5, the resulting gradual change in conductance is very smooth and reproducible.

In FIG. 4, various curves 300, 305, 310, 315 and 320 a progressive increase of the conductance for various memory components, of the type of the memory components W_{BLb,ij}, W_{BL,ij}, M_{BLb,ij}, M_{BL,ij}, included in the memory cells 20. Further to multiple measures obtained for a high number of memory components, such as 4096 memory components, a mean curve 350 representing the mean of said measured conductances, together with a lower curve 360 and an upper curve 370 representing the standard deviation of said measured conductances from this mean were obtained. These mean curve 350, lower curve 360 and upper curve 370 confirm the obtained progressive increase of the conductance for such memory components.

In FIG. 5, a set of curves showing alternating increases and decreases over time in the conductance of said memory components included in the memory cells 20, the conductance increases being obtained with SET pulses and the conductance decreases being due to time drifts. In the example of FIG. 5, SET pulses were applied in successive time instants, namely at 10s, 19s, 28s, etc, for a high number of memory components, such as 4096 memory components, while measuring the conductance; and the results are a mean curve 400 representing the mean of said measured conductances, together with a lower curve 410 and an upper curve 420 representing the standard deviation of said measured conductances from this mean. A model curve 450 represents a modeled evolution of the conductance in these conditions, i.e. with SET pulses applied in successive time instants 10s, 19s, 28s, etc. The comparison of the mean curve 400, lower curve 410 and upper curve 420 with the model curve 450 shows that the model is in line with the measures.

Finally, the curves 500 and 550 represent the model of the drift and progressive SET pulses together, i.e. alternating increases and decreases over time in the conductance, for two respective memory components, such two complementary primary memory components W_{BLb,ij}, W_{BL,ij}, or else two complementary secondary memory components M_{BLb,ij}, M_{BL,ij}.

Therefore, said curves 500 and 550 confirm the ability to encode each binary weight W_{bin,ij} using two complementary primary memory components W_{BLb,ij}, W_{BL,ij}, and respectively to encode each latent variable mᵢⱼ is encoded using two complementary secondary memory components M_{BLb,ij}, M_{BL,ij}.

After the training phase 100, the electronic circuit 10 performs the inference phase 110 using the binarized neural network 15 trained during the training phase 100.

The inference phase 110 is performed in the same manner than the forward pass, with the binarized neural network 15 in its trained version, instead of the binarized neural network 15 in its initial untrained version. Accordingly, equation (1) is used for calculating the output values of the neurons of a respective current layer, from the input values received by the neurons of the respective current layer, namely the output values of the neurons of the previous layer.

Thus, with the electronic circuit 10 and the training method according to the invention, each latent variable mᵢⱼ is encoded using at least one secondary memory component M_{BLb,ij}, M_{BL,ij}, each secondary memory component M_{BLb,ij}, M_{BL,ij} having a characteristic, such as conductance, subject to a time drift.

Therefore, the value of each latent variable mᵢⱼ drifts over time, in a similar manner to each latent weight verifying an exponential moving average of gradients according to the BOP algorithm for training BNN.

Thus, the electronic circuit 10 and the training method use this characteristic, such as the conductance, of the secondary memory components M_{BLb,ij}, M_{BL,ij} subject to the time drift to adapt the BOP algorithm for training the binarized neural network 15, so as to enable a full on-chip training of the binarized neural network 15.

Accordingly, while it has not been possible to train a binarized neural network without computer support with the prior art training methods, the electronic circuit 10 and the training method according to the invention allow a complete on-chip training of the binarized neural network 15 without computer support.

1. Method for training a binarized neural network, the binarized neural network including input neurons for receiving input values, output neurons for delivering output values and intermediate neurons between the input and output neurons, a respective binary weight being associated to each connection between two respective neurons, the method being implemented by an electronic circuit and comprising:
a forward pass including calculating an output vector by applying the binarized neural network on an input vector in a forward direction from the input neurons to the output neurons;
a backward pass including computing an error vector between the calculated output vector and a learning output vector and calculating a new value of the input vector by applying the binarized neural network on the error vector in a backward direction from the output neurons to the input neurons; and
a weight update including, for each binary weight:
computing a product by multiplying a respective element of the error vector with a respective element of the new value of the input vector;
modifying a latent variable depending on the product; and
updating the respective binary weight as a function of the latent variable with respect to a threshold;
each binary weight being encoded using at least one primary memory component;
each latent variable being encoded using at least one secondary memory component, each secondary memory component having a characteristic subject to a time drift,
each one of the primary and secondary memory components being a phase-change memory device.

2. Method according to claim 1, wherein each primary memory component has a characteristic subject to a time drift.

3. Method according to claim 1, wherein the characteristic subject to the time drift is a conductance.

4. Method according to claim 1, wherein each binary weight is encoded using two complementary primary memory components connected to a common sense line.

5. Method according to claim 4, wherein the characteristic subject to the time drift is a conductance, and each binary weight depends on respective conductance of the two complementary primary memory components.

6. Method according to claim 5, wherein each binary weight verifies the following equation:
$$Wbin , ij = sign ( \frac{G ( {W}_{BLb , ij} )}{G ( {W}_{BL , ij} )} )$$
where W_{bin,ij} represents a respective binary weight,
sign is a sign function applied to an operand and issuing the value 1 if the operand is positive and −1 if the operand is negative, and
G(W_{BLb,ij}) and G(W_{BL,ij}) are the respective conductance of the two complementary primary memory components.

7. Method according to claim 1, wherein each latent variable is encoded using two complementary secondary memory components connected to a common sense line.

8. Method according to claim 7, wherein the characteristic subject to the time drift is a conductance, and each latent variable depends on respective conductances of the two complementary secondary memory components.

9. Method according to claim 8, wherein each latent variable verifies the following equation:
mᵢⱼ=G(M_{BLb,ij})−G(M_{BL,ij})
where mᵢⱼ represents a respective latent variable, and
G(M_{BLb,ij}) and G(M_{BL,ij}) are the respective conductance of the two complementary secondary memory components.

10. Method according to claim 1, wherein during the weight update, each latent variable is modified depending on the sign of the respective product.

11. Method according to claim 10, wherein each latent variable is increased if the respective product is positive, and conversely decreased if said product is negative.

12. Method according to claim 8, wherein the characteristic subject to the time drift is a conductance, and each binary weight depends on respective conductance of the two complementary primary memory components, and
wherein during the weight update, each binary weight is updated according to an algorithm including following first and second cases:
first case: if G(W_{BLb,ij})<G(W_{BL,ij}) and G(M_{BLb,ij})>G(M_{BL,ij})+Threshold1 then switch to G(W_{BLb,ij})>G(W_{BLb,ij}),
second case: if G(W_{BL,ij})<G(W_{BLb,ij})and (G(M_{BL,ij})>G(M_{BLb,ij})+Threshold2 then switch to G(W_{BLb,ij})>G(W_{BLb,ij}),
where G(W_{BLb,ij}) and G(W_{BL,ij}) are the respective conductance of the two complementary primary memory components,
G(M_{BLb,ij}) and G(M_{BL,ij}) are the respective conductance of the two complementary secondary memory components, and
Threshold1, Threshold2 are respective thresholds.

13. Method according to claim 12, wherein the algorithm consists of said first and second cases.

14. Method according to claim 12, wherein switch to G(W_{BLb,ij})>G(W_{BL,ij}) is done by increasing G(W_{BLb,ij}).

15. Method according to claim 12, wherein Threshold1 is equal to (G(W_{BLb,ij})−G(W_{BL,ij})).

16. Method according to claim 12, wherein switch to G(W_{BL,ij})>G(W_{BLb,ij}) is done by increasing G(W_{BLb,ij}).

17. Method according to claim 12, wherein Threshold2 is equal to (G(W_{BL,ij})−G(W_{BLb,ij}))).

18. Method according to claim 1, wherein increasing the conductance of a respective memory component is obtained by applying a SET pulse to the corresponding phase-change memory device.

19. Method according to claim 18, wherein the SET pulse is a low current pulse with a long duration, and a RESET pulse is a high current pulse with a short duration.

20. Electronic circuit for operating a binarized neural network, the binarized neural network including input neurons for receiving input values, output neurons for delivering output values and intermediate neurons between the input and output neurons, a respective binary weight being associated to each connection between two respective neurons, a training of the binarized neural network comprising:
a forward pass including calculating an output vector by applying the binarized neural network on an input vector in a forward direction from the input neurons to the output neurons;
a backward pass including computing an error vector between the calculated output vector and a learning output vector and calculating a new value of the input vector by applying the binarized neural network on the error vector in a backward direction from the output neurons to the input neurons; and
a weight update including, for each binary weight, computing a product by multiplying a respective element of the error vector with a respective element of the new value of the input vector; modifying a latent variable depending on the product; and updating the respective binary weight as a function of the latent variable with respect to a threshold;
the electronic circuit comprising a plurality of memory cells, each memory cell being associated to a respective binary weight, each memory cell including at least one primary memory component for encoding the respective binary weight;
each memory cell further including at least one secondary memory component for encoding a respective latent variable, each latent variable being used for updating the respective binary weight, each secondary memory component having a characteristic subject to a time drift,
each one of the primary and secondary memory components being a phase-change memory device.

21. Electronic circuit according to claim 20, wherein the electronic circuit further comprises:
a plurality of primary word lines to command the primary memory components;
a plurality of secondary word lines to command the secondary memory components;
a plurality of sense lines and bit lines connected to the memory cells;
a first control module to control the primary word lines, the secondary word lines and the sense lines; and
a second control module to control the bit lines.

22. Electronic circuit according to claim 21, wherein a respective sense line is connected to both primary and secondary memory components of a corresponding memory cell.

23. Electronic circuit according to claim 21, wherein a respective bit line is connected to both primary and secondary memory components of a corresponding memory cell.
